(19) United States
(12) Patent Application Publication
(10) Pub. No.: US 2026/0367121 A1
(43) Pub. Date: Nov. 19, 2026

(54) METHOD FOR PREDICTING MAXIMUM POWER POINT VOLTAGE, AND POWER CONVERSION DEVICE USING SAME

(71) Applicant: HANWHA SOLUTIONS CORPORATION, Seoul (KR)

(72) Inventors: Seonghoon HA, Seoul (KR); Jongwoo BAE, Seoul (KR); Jongwon SONG, Seoul (KR); Seonghun LEE, Seoul (KR); Juhwan YUN, Seoul (KR)

(21) Appl. No.: 19/126,257

(22) PCT Filed: Jul. 30, 2024
(86) PCT No.: PCT/KR2024/011114

§ 371 Date: May 1, 2025

(30) Foreign Application Priority Data
Aug. 2, 2023 (KR) 10-2023-0101083

(51) Int. Cl. G01R 21/14; G05B 15/02; H02J 3/38; H02J 101/24; H02S 50/10

(52) U.S. Cl. CPC G01R 21/14; G05B 15/02; H02J 3/38; H02S 50/10; H02J 2101/25

(57) ABSTRACT

Module-level power electronics (MPLE) according to an aspect includes: a converter; and a processor; wherein the processor is configured to calculate, by using characteristic information according to a reference condition of a photovoltaic module connected to the converter, a first maximum power point voltage according to a measured first output power of the photovoltaic module at a reference temperature, and correct the first maximum power point voltage to a second maximum power point voltage corresponding to a current temperature.

### TECHNICAL FIELD

The present disclosure relates to a method of predicting a maximum power point voltage and power electronics using the same.

### BACKGROUND ART

A solar power generation system may include module-level power electronics (MLPE) (or, a module-level power control device) to increase power generation under certain conditions (for example, when photovoltaic modules are shaded).

The MLPE is connected to each photovoltaic module and performs maximum power point tracking (MPPT) control to optimize the output voltage of the photovoltaic module.

According to a typical MPPT algorithm, power fluctuations are monitored from voltage fluctuations on the photovoltaic module side to calculate a maximum power point (MPP). However, when following a typical MPPT algorithm, efficiency may be reduced due to unnecessary voltage fluctuations or switching losses caused by excessive switching operations. Furthermore, when MPPT control is performed simultaneously on both the MLPE and an inverter, this dual implementation of MPPT control is inefficient.

### DISCLOSURE OF INVENTION

### Technical Problem

The technical problem of the present disclosure is to provide a method of predicting maximum power point voltage and power electronics using the same.

### Solution to Problem

One aspect provides power electronics including: a converter for receiving an output voltage of a photovoltaic module and converting the voltage; and a processor; wherein the processor is configured to calculate a first maximum power point voltage according to a measured first output power of the photovoltaic module at a reference temperature by using characteristic information according to a reference condition of a photovoltaic module connected to the converter, and correct the first maximum power point voltage to a second maximum power point voltage corresponding to a currently assumed temperature of the photovoltaic module.

Another aspect provides a photovoltaic module including the power electronics.

Another aspect provides a method of predicting a maximum power point voltage performed by power electronics of a photovoltaic module, the method including: calculating a first maximum power point voltage according to a measured first output power of the photovoltaic module at a reference temperature by using characteristic information of the photovoltaic module connected to a converter; and correcting the first maximum power point voltage to a second maximum power point voltage corresponding to a current temperature.

Another aspect provides a computer-readable recording medium according to another aspect includes a recording medium having recorded thereon a program for causing a computer to execute the method.

### BRIEF DESCRIPTION OF DRAWINGS

FIG. 1 is a schematic diagram illustrating an example of a photovoltaic module including power electronics according to an embodiment.

FIG. 2 is a schematic diagram illustrating an example of power electronics according to an embodiment.

FIG. 3 is a diagram illustrating an example of a detailed circuit of a photovoltaic module including power electronics according to an embodiment.

FIG. 4 is a diagram illustrating an example of an operation flow according to an embodiment.

FIG. 5 is a diagram illustrating an example of power electronics receiving characteristic information according to an embodiment.

FIG. 6 is a diagram illustrating an example of characteristic information according to an embodiment.

FIG. 7 is a diagram illustrating an example of the relationship between an output power and a maximum power point voltage of a photovoltaic module according to an embodiment.

### BEST MODE FOR CARRYING OUT THE INVENTION

Module-level power electronics (MPLE) according to an aspect include: a converter, and a processor, wherein the processor is configured to calculate a first maximum power point voltage according to a measured first output power of the photovoltaic module at a reference temperature by using characteristic information according to a reference condition of a photovoltaic module connected to the converter, and correct the first maximum power point voltage to a second maximum power point voltage corresponding to a current temperature of the photovoltaic module.

### Mode for the Invention

The terms used in embodiments have been selected to be those generally widely used at present, but these may vary according to the intention of a skilled person in the field, precedents, or the emergence of new technologies. Also, in certain cases, there are terms arbitrarily selected by the applicant, and in these cases, the meaning will be described in detail in the relevant explanatory portion. Therefore, the terms used in the specification should be defined based not simply on the names of the terms but on their meanings and the content throughout the specification.

When it is stated throughout the specification that one part “includes” a certain component, this means, unless specifically stated otherwise, that other components are not excluded but may be additionally included.

Furthermore, terms such as “unit,” “module,” etc., described in in the specification refer to a unit that processes at least one function or operation, which may be implemented in hardware or software, or a combination of hardware and software.

Additionally, terms including ordinals such as “first” or “second” and the like used in the specification may be used to describe various components, but the components should not be limited by these terms. These terms may be used to distinguish one component from another.

Hereinafter, preferred embodiments of the present disclosure will be described in detail with reference to the attached drawings. The detailed description to be disclosed below with the accompanying drawings is intended to describe embodiments of the present disclosure and is not intended to represent the only embodiments in which the present disclosure may be practiced. Parts unrelated to the description may be omitted from the drawings to clearly explain the present disclosure, and the same or similar reference numerals may be used for the same or similar components throughout the specification.

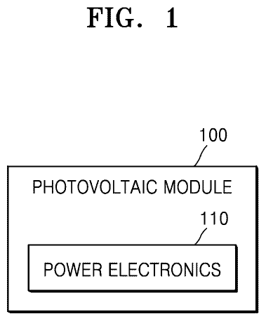

FIG. 1 is a schematic diagram illustrating an example of a photovoltaic module including power electronics according to an embodiment.

FIG. 1 illustrates a photovoltaic module 100 and power electronics 110. Although FIG. 1 illustrates that the power electronics 110 is included within the photovoltaic module 100, the present embodiment is not limited thereto. In other words, the power electronics 110 may be a device independent of the photovoltaic module 100.

The photovoltaic module 100 is a module that produces electricity using solar energy. For example, a plurality of photovoltaic modules, each being the photovoltaic module 100, may be connected to form a photovoltaic module array.

The power electronics 110 is a device connected to the photovoltaic module 100 to optimize the output power (output voltage) of the photovoltaic module 100. For example, the power electronics 110 may be a micro-inverter or a direct current (DC) optimizer.

In some embodiments, when the power electronics 110 is a DC optimizer, a single DC optimizer may be connected to a single photovoltaic module 100. In some embodiments, the DC optimizer may be connected to an inverter (e.g., a string inverter). In this case, the DC optimizer may optimize the power output from the photovoltaic module 100 and output the same to an inverter. The current converted by the inverter (e.g., direct current to alternating current) may be output to a load or the power grid.

In some embodiments, when the power electronics 110 is a micro inverter, a single micro inverter may be connected to a single photovoltaic module 100. In this case, the micro inverter may convert the power generated from the photovoltaic module 100, and the converted current may be output to a load or a power grid.

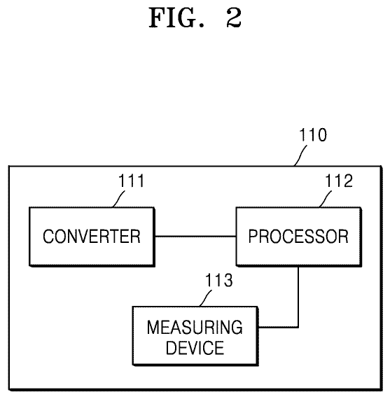

The power electronics 110 may be module-level power electronics (MLPE) connected to the photovoltaic module 100, but is not limited thereto. For example, the power electronics 110 may be MLPE and may be included in an inverter. An example of the power electronics 110 will now be described with reference to FIG. 2.

The power electronics 110 may optimize the output voltage of the photovoltaic module 100 through maximum power point tracking control. The power electronics 110 may calculate a maximum power point voltage by performing a maximum power point tracking control to track the voltage when the photovoltaic module 100 generates maximum power. For example, a maximum power point tracking algorithm is an algorithm that continuously adjusts the impedance of the photovoltaic module 100 or the impedance of a photovoltaic module array such that a photovoltaic power generation system operates at the maximum power point when conditions such as solar irradiance, temperature, and load change.

For example, the power electronics 110 may be connected to the photovoltaic module 100 in a one-to-one correspondence, but is not limited thereto. Depending on the structure adopted by the photovoltaic power generation system, the power electronics 110 may be provided in a many-to-one or many-to-many manner on the photovoltaic modules 100, and the installation configured is not limited thereto. In some embodiments, when a plurality of power electronics are provided each being the power electronics 110, the power electronics may be connected in series with each other. When the power electronics 110 is a DC optimizer, the power electronics 110 constituting opposite ends of the plurality of power electronics 110 connected in series may be connected to an inverter (e.g., a string inverter).

The inverter may be a component provided in a power conversion system (PCS) to perform power conversion to supply power produced from a photovoltaic module 100 to a load or a grid. For example, the inverter may monitor the operating status by analyzing various data received from the photovoltaic module 100, the power electronics 110, the load, the power system, etc.

In general, the power electronics 110 may perform maximum power point tracking control to find the maximum power point voltage by varying the voltage or performing switching control, etc. During this process, power loss may occur. In addition, when the inverter performs maximum power point tracking control together with the power electronics 110, double switching operation may occur in the solar power generation system.

The characteristics of photovoltaic cells, such as cell output voltage and current, change depending on the amount of solar irradiance and cell temperature. Accordingly, suppliers of the photovoltaic module 100 measure the characteristics of the photovoltaic module 100 including photovoltaic cells in advance and provide the characteristics information to consumers.

Hereinafter, a method of calculating the maximum power point voltage MPP of the photovoltaic module 100 using characteristic information of the photovoltaic module 100 is proposed.

For example, a method according to an embodiment may minimize voltage fluctuations in a maximum power point trace MPPT method such as a P&O algorithm. Accordingly, when the method according to an embodiment is used, power loss may be prevented during the process of maximum power point tracking control.

Hereinafter, the operation of the power electronics 110 included in a photovoltaic module 100 according to an embodiment of the present disclosure will be specifically described with reference to the drawings.

FIG. 2 is a schematic diagram illustrating an example of power electronics according to an embodiment.

Referring to FIG. 2, the power electronics 110 may include a converter 111, a processor 112, and a measuring device 113.

The converter 111 is a device that converts the voltage applied from the photovoltaic module 100 (output voltage of the photovoltaic module 100). For example, the converter 111 may include a DC optimizer, a DC/alternating current (AC) inverter, or a micro inverter.

For example, when the converter 111 is a DC optimizer, the converter 111 may be implemented as a buck converter that steps down the input voltage. In some embodiments, the converter 111 may be implemented as a buck and boost converter. However, examples of the converter 111 are not limited to those described above.

For example, the processor 112 may include a microcontroller unit (MCU) for power control. The processor 112 may execute software such as a program to control at least one other component (e.g., hardware or software component) of the power electronics 110 and perform various data processing or calculations.

The processor 112 may perform serial communication with an inverter or power line communication (PLC) to receive characteristic information of the photovoltaic module 100 or receive control signals, shutdown signals, etc. required for power optimization.

The processor 112 may control the duty ratio of the converter 111 to convert (regulate) the output voltage of the power electronics 110.

The measuring device 113 may include a temperature sensor. For example, a temperature sensor may be used to measure the temperature Tₘₗₚₑ of a photovoltaic module 100 by measuring the temperature Tₚᵥ of power electronics 110.

In some embodiments, the measuring device 113 may further include a current sensor for measuring the output current Iₚᵥ of the photovoltaic module 100 at the output terminal of the photovoltaic module 100 and a voltage sensor for measuring the output voltage Vₚᵥ of the photovoltaic module 100.

However, the configuration and operation of the power electronics 110 are not limited to what is described above. For example, the processor 112 may receive the output current Iₚᵥ and output voltage Vₚᵥ of the photovoltaic module 100 measured by an external device.

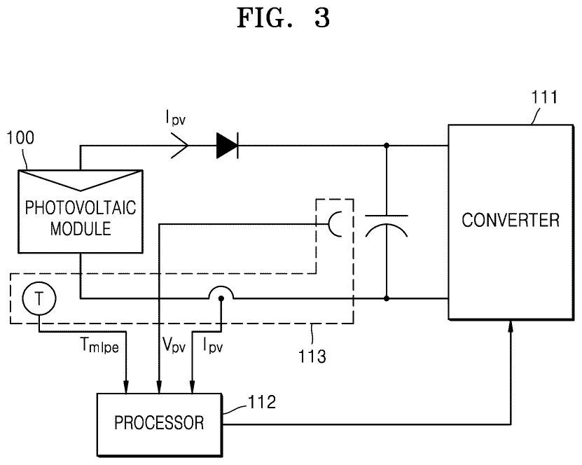

FIG. 3 is a diagram illustrating an example of a detailed circuit of a photovoltaic module including power electronics according to an embodiment.

FIG. 3 illustrates detailed configurations of the photovoltaic module 100 and the power electronics 110.

The processor 112 may receive, from the measuring device 113, the output current Iₚᵥ of the photovoltaic module 100, the output voltage Vₚᵥ of the photovoltaic module 100, and the temperature Tₘₗₚₑ of the photovoltaic module 100. In some embodiments, the processor 112 may use the received information to calculate the maximum power point voltage Vₘₚ. In some embodiments, the processor 112 may control the converter 111 to drive the output voltage Vₚᵥ of the photovoltaic module 100 to the maximum power point voltage Vₘₚ.

Hereinafter, an embodiment in which the processor 112 calculates the maximum power point voltage Vₘₚ, will be described.

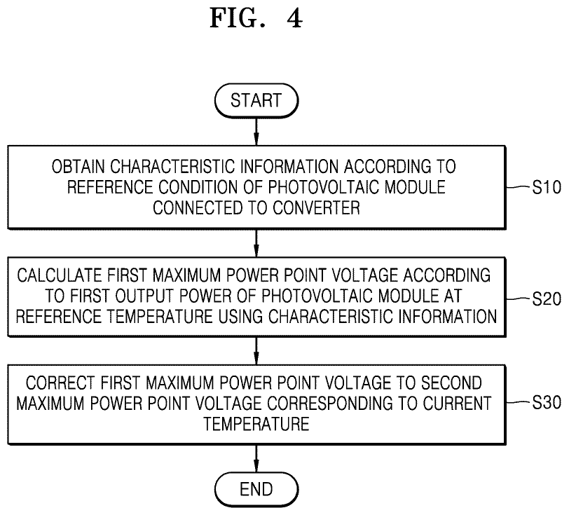

FIG. 4 is a diagram illustrating an example of an operation flow of power electronics according to an embodiment.

Referring to FIG. 4, the processor 112 may obtain characteristic information according to a reference condition of the photovoltaic module 100 connected to the converter 111 (S10).

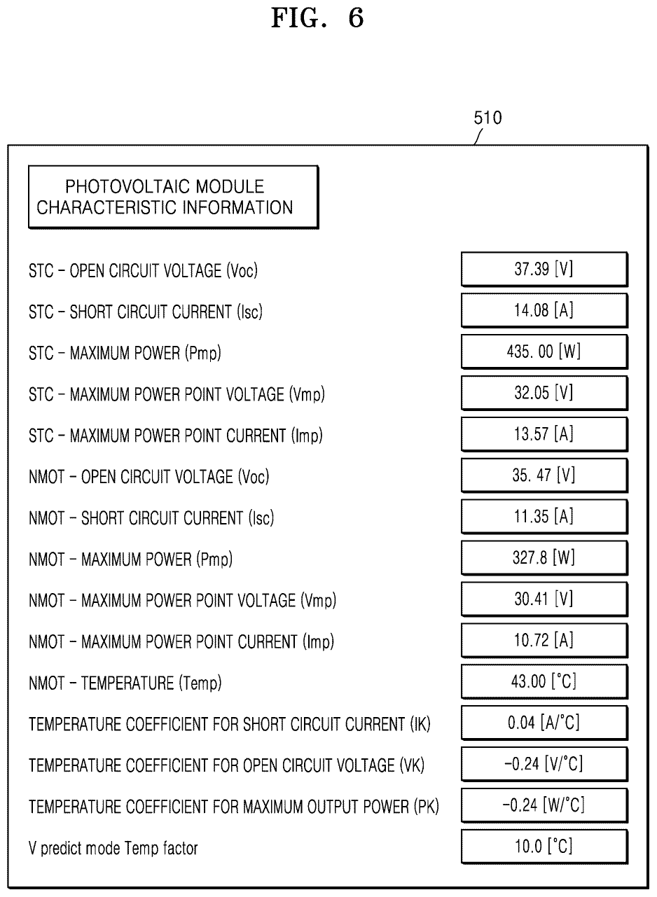

Typically, manufacturers of the photovoltaic module 100 provide information on the characteristics of the photovoltaic module 100 to consumers. The characteristic information may be information measuring the performance of the photovoltaic module 100 under a reference condition. For example, the characteristic information may include maximum output power (Pmpp), short-circuit current (Isc), open circuit voltage (Voc), maximum output current (Impp), maximum output voltage (Vmpp), efficiency (η), temperature coefficient (α) for short-circuit current (Isc), temperature coefficient (β) for open circuit voltage (Voc), and temperature coefficient (γ) for maximum output power (Pmpp) of the photovoltaic module 100. An example of characteristic information will be described below with reference to FIG. 6.

For example, a reference condition may include standard test conditions (STC) or nominal module operating temperature (NMOT). In this regard, STC refers to a reference condition including the temperature of 25 °C±2 °C, the solar irradiance of 1000 W/m², and the air mass (AM) of 1.5 G, and NMOT refers to a reference condition including the temperature of 43 °C, the solar irradiance of 800 W/m², and AM of 1.5 G.

The processor 112 may obtain two or more pieces of characteristic information having different reference conditions. In this regard, the characteristic information may be distinguished into first characteristic information according to a first reference condition and second characteristic information according to a second reference condition.

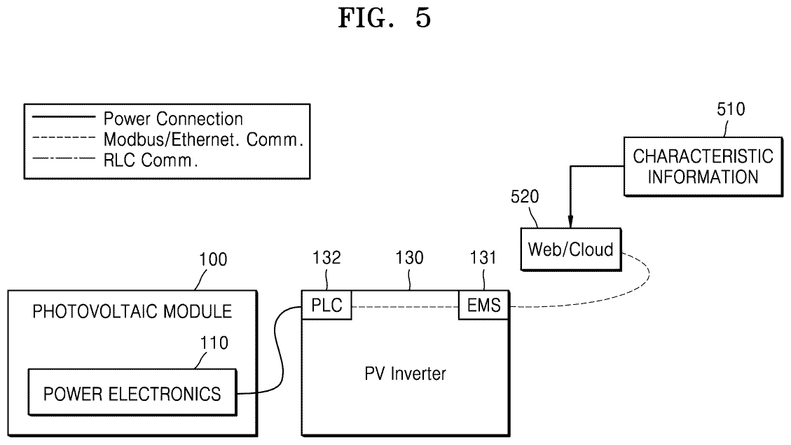

Meanwhile, the processor 112 may also receive the characteristic information by integrating the same into a single reception signal. There may be various ways in which the processor 112 obtains characteristic information. For example, the processor 112 may receive characteristic information from a PLC device via power line communication. An example of the processor 112 obtaining characteristic information is described below with reference to FIG. 5.

Hereinafter, for convenience of explanation, the first reference condition is assumed to be the standard test condition STC and the second reference condition is assumed to be the nominal module operating temperature NMOT.

The processor 112 may be configured to calculate the first maximum power point voltage according to the first output power of the photovoltaic module 100 at a reference temperature using the characteristic information (S20).

For example, the relationship between the amount of solar irradiance and the short-circuit current I_{sc} of the photovoltaic module 100, and the relationship between the short-circuit current I_{sc} and the open circuit voltage V_{oc} of the photovoltaic module 100 may be expressed as in Mathematical Formulas 1 and 2.

$${I}_{sc} ( T , Q ) = {I}_{sc} \times Q \times \frac{1}{( 1 - β ( T - 25 ) )} \qquad [ Mathematical Expression 1 ]$$

(I_{sc}: short-circuit current, Q: solar irradiance, T: module temperature, β: Boltzmann constant)

$${V}_{oc} = \frac{nKT}{q} ln ( \frac{{I}_{sc}}{{I}_{o}} + 1 ) \qquad [ Mathematical Expression 2 ]$$

I_{sc}: short-circuit current, V_{oc}: open circuit voltage, Iₒ: dark current of photovoltaic cell

Referring to Mathematical Expression 1, the short-circuit current I_{sc} may be proportional to the solar irradiance Q (the solar irradiance Q is proportional to the maximum power Pₘₚ), and the open circuit voltage V_{oc} may be proportional to the natural logarithm of the short-circuit current I_{sc}. Therefore, the relationship of Mathematical Expression 3 may be derived. However, it is assumed that I_{sc} is sufficiently larger than Iₒ.

$$\frac{{V}_{oc}}{{V}_{oc ( STC )}} ∝ \frac{ln ( {I}_{sc} )}{ln ( {I}_{sc ( STC )} )} ∝ \frac{ln ( Q )}{ln ( {Q}_{( STC )} )} ∝ \frac{ln ( {P}_{mp} )}{ln ( {P}_{mp ( STC )} )} \qquad [ Mathematical Expression 3 ]$$

That is, the open circuit voltage V_{oc} may be proportional to the natural logarithm of the maximum power Pₘₚ. Therefore, when the relationship of the open circuit voltage V_{oc} and the maximum power Pₘₚ can be defined as the relationship of the maximum power point voltage Vₘₚ and the power P, the maximum power point voltage for the power output by the photovoltaic module 100 can be predicted.

To this end, the processor 112 may be configured to calculate the rate of change of the maximum power point voltage for the output power of the photovoltaic module at a reference temperature using the first characteristic information and the second characteristic information, and calculate a maximum power point voltage using the rate of change. Hereinafter, the process by which the processor 112 calculates the maximum power point voltage is specifically described.

First, the processor 112 may be configured to calculate the rate of change (hereinafter referred to as “first rate of change”) of the open circuit voltage V_{oc} with respect to the natural logarithm of the maximum power Pₘₚ of the photovoltaic module 100 at a reference temperature by using the open circuit voltage V_{oc} and the maximum power Pₘₚ of the photovoltaic module 100 under the first reference condition and the second reference condition.

As described above, the open circuit voltage V_{oc} (corresponding to the maximum power point voltage Vₘₚ) (X) and the natural logarithm of the maximum power Pₘₚ (Y) may have a proportional relationship, that is, a linear relationship (Y=aX+b, where a and b are constants).

In the present disclosure, a relational expression may be derived using two (X, Y) coordinates included in first characteristic information and second characteristic information of different reference conditions.

However, in the case of the first reference condition and the second reference condition, since reference temperatures thereof are different from each other, it is necessary to convert one value to match with the other reference temperature.

The processor 112 may be configured to convert the open circuit voltage and maximum power of the photovoltaic module 100 included in either the first characteristic information or the second characteristic information to correspond to a reference temperature. For example, in the case of the reference temperature of the first reference condition (STC), the open circuit voltage V_{oc(NMOT)} and maximum power P_{mp(NMOT)} of the photovoltaic module included in the second characteristic information follow the second reference condition (NMOT). Therefore, the open circuit voltage V_{oc(NMOT)} and maximum power P_{mp(NMOT)} of the photovoltaic module may be converted to correspond to the reference temperature of the first reference condition (STC). Alternatively, in the case of the reference temperature of the second reference condition (NMOT), the open circuit voltage V_{oc(STC)} and maximum power P_{mp(STC)} of the photovoltaic module 100 included in the first characteristic information may be converted to correspond to the reference temperature of the second reference condition (NMOT).

Hereinafter, for convenience of explanation, the first reference condition (STC) is assumed as the standard, and the reference temperature is assumed to be 25 °C.

The processor 112 may be configured to convert the open circuit voltage V_{oc(NMOT)} and power P_{mp(NMOT)} among the second characteristic information according to the second reference condition (NMOT) to correspond to the reference temperature of 25 °C. For example, the processor 112 may be configured to convert the open circuit voltage V_{oc(NMOT)} and power P_{mp(NMOT)} using Mathematical Expression 4 and Mathematical Expression 5.

$${V}_{STC - Conv} ( T ) = \frac{{V}_{oc} ( NMOT )}{1 - {Coef}_{volt} \times ( {T}_{STC} - T ( NMOT ) )} \qquad [ Mathematical Expression 4 ]$$

Mathematical Expression 4 is used to convert the voltage V_{oc(NMOT)} at temperature T to the voltage V(_{STC-Conv)} at STC temperature (TSTC). In Mathematical Expression 4, Coefᵥₒₗₜ is a temperature-voltage coefficient included in the characteristic information, which represents the ratio (%/K) of voltage change (%) per temperature of 1K.

$${P}_{STC - Conv} ( T ) = \frac{{P}_{mp} ( NMOT )}{1 - {Coef}_{power} \times ( {T}_{STC} - T ( NMOT ) )} \qquad [ Mathematical Expression 5 ]$$

Mathematical Expression 5, similar to Mathematical Expression 4, is a formula that converts the power P_{mp(NMOT)} at temperature T into the power P_{STC-Conv} at STC temperature (TSTC). Coef_{power} is a temperature-power coefficient included in the characteristic information, and represents the ratio (%/K) of power change (%) per temperature of 1K.

After unifying the reference temperature according to the two characteristic pieces of information into one, the processor 112 may calculate the first rate of change of the open circuit voltage with respect to the natural logarithm of the maximum power of the photovoltaic module 100 at a reference temperature from the voltage and power calculated by Mathematical Expression 4 and Mathematical Expression 5.

For example, the first rate of change (slope₁) may be expressed by Mathematical Expression 6. Mathematical Expression 6 is described based on the first characteristic condition (STC), but the first characteristic condition (STC) may be replaced with the second characteristic condition (NMOT) or other characteristic information.

$${slope}_{1} = \frac{{V}_{OC ( STC )} - {V}_{OC ( STC - Conv )}}{ln ( {P}_{mp ( STC )} ) - ln ( {P}_{mp ( STC - Conv )} )} \qquad [ Mathematical Expression 6 ]$$

In Mathematical Expression 6, V_{OC(STC)} and P_{mp(STC)} may be the open circuit voltage and maximum power, respectively, under STC conditions and may be obtained from the first characteristic information. V_{OC(STC-Conv)} and P_{mp(STC-Conv)} are the open circuit voltage and the maximum power under the second characteristic condition which have been converted to correspond to the STC temperature, and may be obtained using Mathematical Expression 4 and Mathematical Expression 5.

Meanwhile, the first rate of change is the rate of change between the open circuit voltage and the power, and it is necessary to correct the first rate of change as the rate of change between the maximum power point voltage and the power. Accordingly, the processor 112 may calculate a rate of change (hereinafter referred to as “second rate of change”) of the maximum power point voltage with respect to the natural logarithm of the output power of the photovoltaic module 100 at a reference temperature by using the ratio of the maximum power point voltage V_{mp(STC)} to the open circuit voltage V_{OC(STC)} at the reference temperature. This is expressed as Mathematical Expression 7. However, the ratio of Vₘₚ and V_{oc} is assumed to be the same as

$$\frac{{V}_{mp ( STC )}}{{V}_{oc ( STC )}} .$$

$${slope}_{2} = \frac{{V}_{OC ( STC )} - {V}_{OC ( STC - Conv )}}{ln ( {P}_{mp ( STC )} ) - ln ( {P}_{mp ( STC - Conv )} )} \times \frac{{V}_{mp ( STC )}}{{V}_{OC ( STC )}} \qquad [ Mathematical Expression 7 ]$$

The relationship of power and maximum power point voltage with the second rate of change slope₂ as the slope is as shown in Mathematical Expression 8.

V_{mp-predicted}(Pᵢₙₚᵤₜ)=V_{mp(default)}+slope₂×ln Pᵢₙₚᵤₜ [Mathematical Expression 8]

V_{mp(default)} is an intercept and may be obtained using information included in the characteristic information. Through Mathematical Expression 8, the processor 112 may be configured to predict the maximum power point voltage V_{mp-predicted} (first maximum power point voltage) according to the output power Pᵢₙₚᵤₜ of the photovoltaic module 100. In this regard, the processor 112 may receive information about the output power Pᵢₙₚᵤₜ of the photovoltaic module 100 from the measuring device 113.

The processor 112 may be configured to correct the first maximum power point voltage to a second maximum power point voltage corresponding to the current temperature (S30).

The first maximum power point voltage calculated using mathematical expression 8 is the maximum power point voltage predicted at the reference temperature. Therefore, the maximum power voltage predicted at a reference temperature may be corrected to correspond to the current temperature of the photovoltaic module 100.

Ratio_{Temp}=1+(T_{Current}+T_{Dev}−T_{STC})×Coefᵥₒₗₜ [Mathematical Expression 9]

The processor 112 may be configured to receive information about the Current temperature T_{Current} and may calculate a temperature correction ratio Ratio_{Temp} using the Current temperature T_{Current}, the reference temperature T_{STC}, and the temperature-voltage coefficient Coefᵥₒₗₜ.

In this regard, the processor 112 may be configured to calculate the temperature correction ratio Ratio_{Temp} by further considering the correction temperature T_{dev} for the photovoltaic module 100. The reason why the correction temperature T_{dev} is further considered is because a temperature difference occurs between the photovoltaic module 100 and the power electronics 110. That is, since a temperature sensor is attached to the power electronics 110 and measures the temperature of the power electronics 110, a temperature difference may occur between the photovoltaic module 100 and the power electronics 110. Meanwhile, the correction temperature T_{dev} may vary depending on the accumulated output.

Therefore, when the first maximum power point voltage is corrected to the second maximum power point voltage corresponding to the current temperature by reflecting the temperature correction ratio, it may be expressed as Mathematical Expression 10.

V_{mp-predicted}(Pᵢₙₚᵤₜ,T_{Current})=(V_{mp(default)}+slope₂×ln Pᵢₙₚᵤₜ)×Ratio_{Temp} [Mathematical Expression 10]

As described above, the power electronics 110 may predict the maximum power point voltage using only the power of the photovoltaic module 100, enabling maximum power point tracking control without power loss.

In addition, the power electronics 110 and the inverter do not operate redundantly, and may perform maximum power point tracking control with the predicted maximum power point voltage, which is efficient.

FIG. 5 is a diagram illustrating an example of power electronics receiving characteristic information according to an embodiment.

Referring to FIG. 5, one of the paths through which the power electronics 110 receives the characteristic information 510 will be described. For example, when characteristic information 510 of a photovoltaic module is input through a web/cloud 520, the characteristic information 510 may be transmitted from the web/cloud 520 to an energy management system (EMS) 131. In some embodiments, the characteristic information 510 may be transmitted from the EMS 131 to the power electronics 110 through a programmable logic controller (PLC) 132.

For example, the EMS 131 may receive the characteristic information 510 from the web/cloud 520 via Ethernet communication. In some embodiments, the PLC 132 may receive the characteristic information 510 from the EMS 131 via Modbus. In some embodiments, the power electronics 110 may receive the characteristic information 510 from the PLC 132 via PLC communication.

For example, the characteristic information 510 may be automatically entered by recognizing the serial number of the photovoltaic module 100 using a quick response (QR) or bar code, or may be manually entered by a worker. An example of the characteristic information 510 will be described below with reference to FIG. 6.

For example, the PLC 132 may be installed outside the inverter. Meanwhile, the process or method by which the power electronics 110 receives the characteristic information 510 is not limited to what has been described above.

FIG. 6 is a diagram illustrating an example of characteristic information according to an embodiment.

As described above with reference to FIG. 5, the characteristic information 510 may be automatically entered by recognizing the serial number of the photovoltaic module 100 using a QR or bar code, or may be manually entered by a worker.

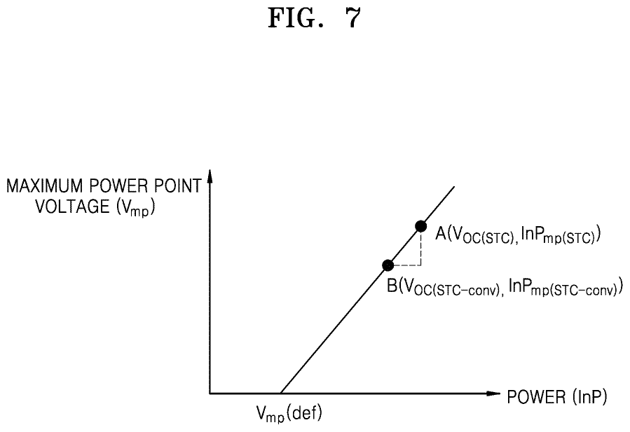

FIG. 7 is a graph illustrating an example of the relationship between an output power and a maximum power point voltage of a photovoltaic module according to an embodiment.

As described above with reference to S20 of FIG. 4, the maximum power point voltage Vₘₚ of the photovoltaic module 100 has a linear relationship (Y=aX+b, and a and b are constants) with the natural logarithm InP of the output power.

Through the first characteristic information and the second characteristic information, the processor 112 may be configured to derive Mathematical Expression 8 by using two points A (V_{OC(STC)}, InP_{mp(STC)}) and B(V_{OC(STC-conv)}, InP_{mp(STC-conv)}) that are already known. In some embodiments, the processor 112 may be configured to derive Mathematical Expression 10 to correspond to the current temperature. The specific operation of the processor 112 is as described above with reference to FIG. 4.

Meanwhile, the method may be written as a program that may be executed on a computer, and may be implemented on a general-purpose digital computer that operates the program using a computer-readable recording medium. Additionally, the structure of the data used in the above-described method may be recorded on a computer-readable recording medium through various means. The computer-readable recording medium includes storage media such as magnetic storage media (e.g., ROM, RAM, USB, floppy disk, hard disk, etc.) and optical readable media (e.g., CD-ROM, DVD, etc.).

A person skilled in the art related to the present embodiment will understand that the present disclosure may be implemented in a modified form without departing from the essential characteristics of the above-described description. Therefore, the disclosed methods should be considered in an illustrative rather than a restrictive sense, and the scope of the claims is set forth in the claims rather than in the foregoing description, and should be construed to include all differences falling within the scope equivalent thereto. The implementations described herein may be implemented, for example, as a method or process, a device, a software program, a data stream or a signal. Even if discussed only in the context of a single form of implementation (e.g., discussed only as a method), the implementation of the discussed feature may also be implemented in other forms (e.g., as a device or a program). The device may be implemented with appropriate hardware, software, firmware, etc. The method may be implemented in a device such as a processor, which generally refers to a processing device including, for example, a computer, a microprocessor, an integrated circuit, or a programmable logic device. The processor also includes communication devices that facilitate communication of information between end-users, and examples thereof are computers, cell phones, personal digital assistants (PDAs), and other devices.

1. Power electronics comprising:
a converter that converts an output voltage of a photovoltaic module; and
a processor, wherein
the processor is configured to calculate a first maximum power point voltage according to a first output power of the photovoltaic module at a reference temperature by using characteristic information according to a reference condition of a photovoltaic module connected to the converter, and correct the first maximum power point voltage to a second maximum power point voltage corresponding to a current temperature.

2. The power electronics of claim 1, wherein
the processor is further configured to obtain first characteristic information according to a first reference condition and second characteristic information according to a second reference condition, and
the first reference condition is different from the second reference condition.

3. The power electronics of claim 2, wherein
the first reference condition includes a standard test condition (STC), and the second reference condition includes a nominal module operating temperature (NMOT).

4. The power electronics of claim 2, wherein
the processor is further configured to calculate a rate of change in a maximum power point voltage for output power of the photovoltaic module at the reference temperature by using the first characteristic information and the second characteristic information, and
calculate the first maximum power point voltage using the rate of change.

5. The power electronics of claim 2, wherein
the processor is further configured to convert an open circuit voltage and a maximum power of the photovoltaic module included in one of the first characteristic information and the second characteristic information to correspond to the reference temperature.

6. The power electronics of claim 1, wherein
the processor is further configured to receive information about a current temperature measured through a temperature sensor.

7. The power electronics of claim 6, wherein
the processor is further configured to:
calculate a temperature correction ratio using the current temperature, a reference temperature, and a temperature-voltage coefficient; and
correct the first maximum power point voltage to the second maximum power point voltage by using the temperature correction ratio.

8. The power electronics of claim 7, wherein
the processor is further configured to calculate the temperature correction ratio by further considering a correction temperature for the photovoltaic module.

9. The power electronics of claim 1, wherein
the power electronics includes module-level power electronics (MPLE).

10. The power electronics of claim 1, wherein
the power electronics is built into an inverter.

11. A photovoltaic module comprising
the power electronics according to claim 1.

12. A method of predicting a maximum power point voltage performed by power electronics of a photovoltaic module, the method comprising:
calculating a first maximum power point voltage according to a first output power of the photovoltaic module at a reference temperature by using characteristic information of the photovoltaic module connected to a converter; and
correcting the first maximum power point voltage to a second maximum power point voltage corresponding to a current temperature.

13. The method of claim 12, wherein
the calculating the first maximum power point voltage comprises:
calculating a first rate of change of open circuit voltage for maximum power of the photovoltaic module at the reference temperature by using first characteristic information according to a first reference condition and second characteristic information according to a second reference condition different from the first reference condition;
calculating a second rate of change of a maximum power point voltage for output power of the photovoltaic module at the reference temperature by using a ratio of a maximum power point voltage to an open circuit voltage at the reference temperature; and
calculating the first maximum power point voltage using the second rate of change.

14. The method of claim 13, wherein
the first reference condition includes a standard test condition (STC), and the second reference condition includes a nominal module operating temperature (NMOT).

15. The method of claim 13, wherein
the calculating the first rate of change comprises
converting an open circuit voltage and maximum power of the photovoltaic module included in one of the first characteristic information and second characteristic information to correspond to the reference temperature.

16. The method of claim 15, wherein
the correcting to the second maximum power point voltage comprises:
receiving information about a current temperature measured through a temperature sensor;
calculating a temperature correction ratio using the current temperature, a reference temperature, and a temperature-voltage coefficient; and
multiplying the first maximum power point voltage by the temperature correction ratio to correct to the second maximum power point voltage.

17. The method of claim 16, wherein
in the calculating the temperature correction ratio,
the temperature correction ratio is calculated in consideration of a correction temperature for the photovoltaic module.

18. The method of claim 12, wherein
the power electronics comprises module-level power electronics (MPLE).

19. The method of claim 12, wherein
the power electronics is built into an inverter.

20. A computer-readable recording medium having recorded thereon a program for causing a computer to execute the method of claim 12.
